(19) United States
(12) Patent Application Publication
(10) Pub. No.: US 2003/0034771 A1
(43) Pub. Date: Feb. 20, 2003

(54) Low-leakage automatic test equipment active load

(76) Inventor: Charles Scott Sharman, Colorado Springs, CO (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/929,964

(22) Filed: Aug. 14, 2001

(51) Int. Cl. G01R 31/26

(52) U.S. Cl. 324/158.1

(57) ABSTRACT

A load for automatic testing of a device. The load includes a transistor bridge and a protection circuit. The transistor bridge has a plurality of transistors, and provides low leakage current during an off-state of the load system. The protection circuit protects base-emitter junctions of the transistors from a large reverse bias voltage.

### BACKGROUND

The present invention relates to automatic test equipment (ATE). More particularly, the present invention relates to providing a low-leakage active load for such an ATE.

Integrated circuits after being fabricated and packaged are typically tested on automatic test equipment (ATE) before being shipped to customers. Devices not passing certain tests are typically discarded and not shipped. Accordingly, testing accuracy plays a vital role in the design of test equipment because a discrepancy in measurements may result in an incorrect classification of a device under test (DUT). For example, in some testing environments, the DUT is categorized as a valid device for sale. To pass as a valid device, each pin of a given DUT should typically satisfy both timing and drive strength requirements. Timing requirements may include valid time, hold time, and setup time. Drive strength requirements may include driving an output to a predetermined voltage despite an opposing current source load.

The prior art ATE may use a diode bridge system, having a plurality of Schottky diodes, as an active load to determine the drive strength of a DUT output. The diode bridge allows the test equipment to determine the high-state drive capability of a DUT by sourcing current out of the DUT when the DUT is driving an output pin to a high voltage. Alternatively, the diode bridge allows the test equipment to determine the low-state drive capability of a DUT by sinking current into the DUT when the DUT is driving an output pin to a low voltage.

These prior art ATE configurations, however, include disadvantageous features. For example, to properly implement I_{DDq} testing, which is a method for testing very large-scale integrated (VLSI) circuits by detecting elevated levels of quiescent current caused by defects in the circuit, ATE driver/comparator/load (DCL) must have low leakage current. Thus, this leakage current must typically be less than 10 nA over a relatively wide voltage range (e.g. 5V to 8V). But conventional active load Schottky diode bridge architectures suffer from high leakage current. This leakage current may typically be 300 nA or more. Although ATE loads have been implemented with relays to provide low leakage current, relays are less reliable than the DCL, degrade the DCL output waveform, and consume a large footprint.

### SUMMARY

The present invention, in one aspect, describes a load system for a device under test. The system includes a transistor bridge and a protection circuit. The transistor bridge has a plurality of transistors, and provides low leakage current during an off-state of the load system. The protection circuit protects base-emitter junctions of the transistors from a large reverse bias voltage.

In another aspect, the present invention describes a method for providing a load to a DUT pin during automatic testing of a device. The method includes providing a transistor bridge having a plurality of transistors. A state of the load is then determined. The transistor bridge is configured to provide low-leakage current when the load is in an off-state. Base-emitter junctions of the transistors are protected from a large reverse-bias voltage.

### BRIEF DESCRIPTION OF THE DRAWINGS

FIG. 1 is a block diagram of the automatic test equipment Driver/Comparator/Load system in accordance with an embodiment of the present invention.

FIG. 2 shows a conventional active load.

FIG. 3A is a block diagram of an active load system according to an embodiment of the present invention.

FIG. 3B illustrates a schematic diagram of an active load system according to an embodiment of the present invention.

FIG. 4 illustrates V₀ versus V_{DUT} curves for operational states of a transistor bridge according to an embodiment of the present invention.

FIG. 5 is a flowchart illustrating a method for providing an active load to a DUT pin during automatic testing of a device in accordance with an embodiment of the present invention.

### DETAILED DESCRIPTION

In recognition of the above-stated disadvantages associated with prior art designs of automatic test equipment (ATE) driver/comparator/load (DCL), the present invention describes embodiments for designing a load with a transistor bridge. In one embodiment, the transistors are bipolar transistors. Thus, the active load is configured to replace the Schottky diodes in the bridge with bipolar transistors, which exhibit low leakage current in the off-state. Consequently, for purposes of illustration and not for purposes of limitation, the exemplary embodiments of the invention are described in a manner consistent with such use, though clearly the invention is not so limited.

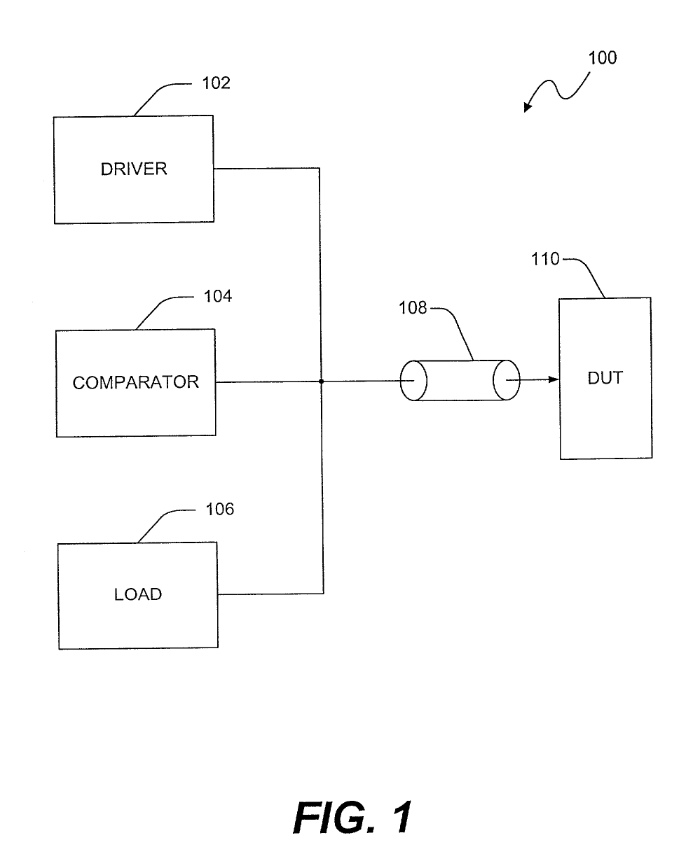

A block diagram of an automatic test equipment DCL system 100 in accordance with an embodiment of the present invention is shown in FIG. 1. The DCL system 100 includes a driver 102, a comparator 104, and a load 106. Each of these components 102, 104, 106 is coupled in common to a pin of a device under test (DUT) 110 through transmission line 108.

The driver 102 is configured to send a digital signal level to the pin of the DUT 110 in response to a control signal indicating that a logical one level (V_{IH}) or a logical zero level (V_{IL}) is to be applied to that pin of the DUT 110. The comparator 104 operates to monitor the digital voltage level of the pin of the DUT 110 to determine whether that voltage level is equal to a minimum acceptable logical one output signal (V_{OH}) level or is less than a maximum allowed logical zero output signal (V_{OL}) level. The load 106 serves to simulate a desired electrical loading condition of the pin of the DUT 110 associated with this portion of the ATE DCL system 100. Thus, the specific pin of the DUT 110 which is being tested by the ATE DCL system 100 is provided with a specified load by the load circuitry 106 in order to determine whether that pin of the DUT 110 is capable of operating properly with the load which is seen by that specific pin during normal operation. In the illustrated embodiment, the load 106 is implemented with a transistor bridge.

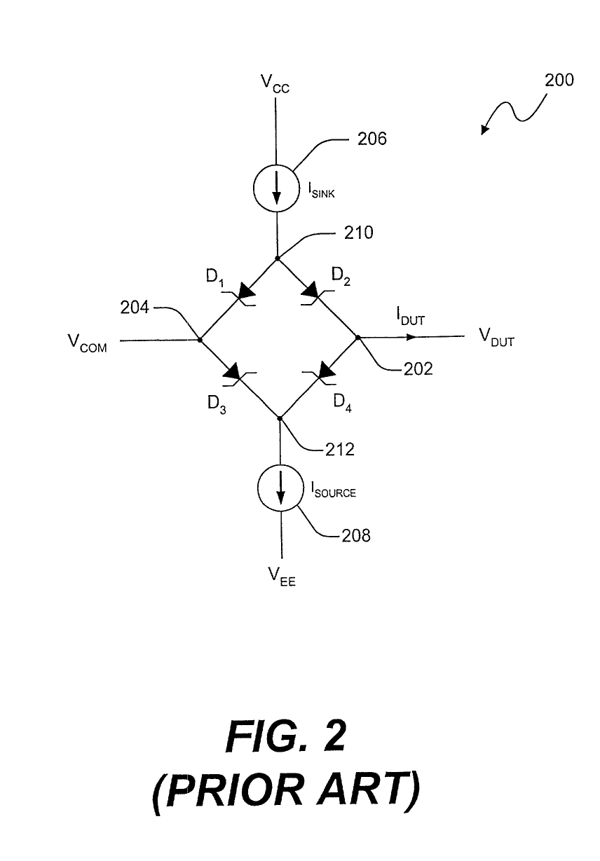

A conventional active load 200, shown in FIG. 2, incorporates a four-terminal diode commutation bridge circuit comprising Schottky diodes D₁ through D₄. The bridge output terminal 202 is connected to the pin of the DUT, and the commutation terminal 204 is supplied with a predetermined commutation voltage, V_{COM}. The current sink 206 and the current source 208 are connected to the current nodes 210, 212 of the diode circuit, respectively. When the active load 200 is in an off-state, the current node 210 is pulled low (i.e. below the lowest allowable voltage level for V_{DUT}) and the current node 212 is pulled high (i.e. above the highest allowable voltage level for V_{DUT}). Thus, the leakage current in the reverse-biased Schottky diodes, D₂ and D₄, cause current leakage at the bridge output terminal 202. This leakage current may typically be 300 nA or more, which is intolerable for certain kinds of tests, such as I_{DDQ} tests.

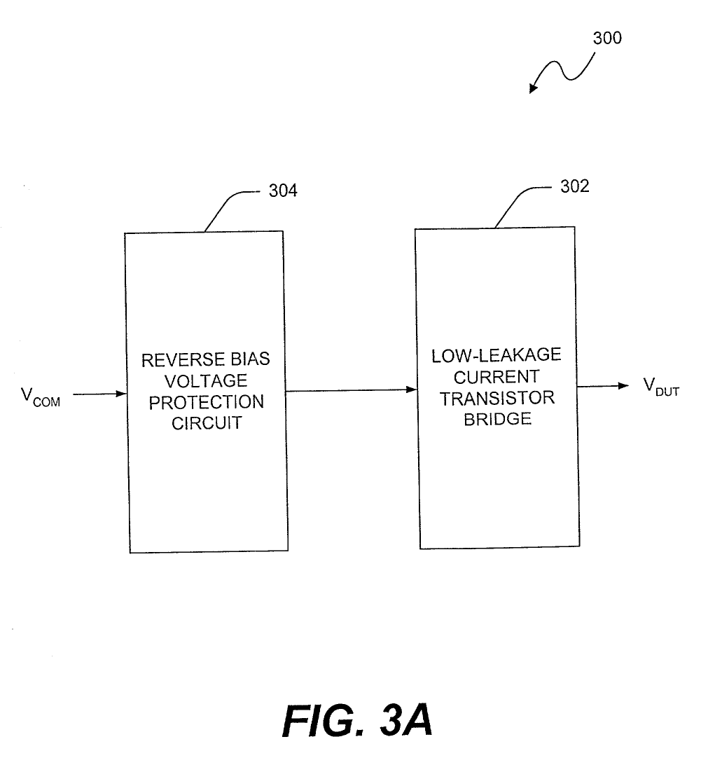

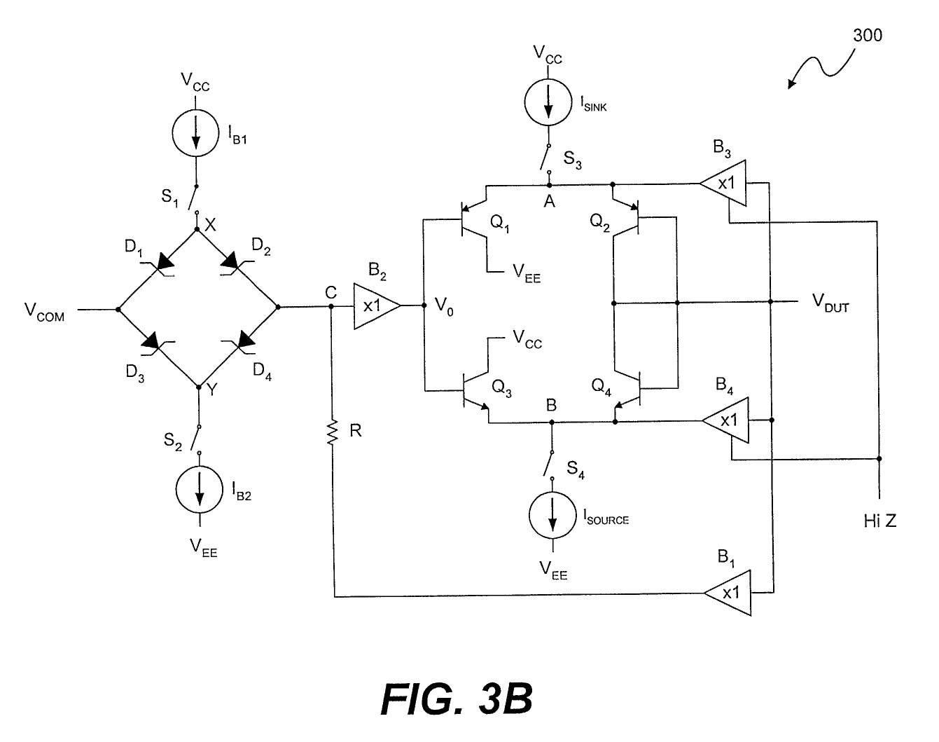

FIG. 3A is a block diagram of an active load system 300 according to an embodiment of the present invention. The load system 300 includes elements that perform substantially similar functions as that of the load circuitry 106 in FIG. 1. A low-leakage current transistor bridge 302 is configured to replace the Schottky diodes in the bridge with bipolar transistors, which exhibit low leakage current in the off-state. In the illustrated embodiment, output of the transistor bridge 302 is tied to a DUT pin with an output voltage V_{DUT}. Thus, the transistor bridge output provides a specified load to the DUT in order to determine whether that DUT is capable of operating properly with the load which is seen by that specific pin during normal operation.

However, the bipolar transistors may have difficulty with a large reverse bias voltage. Therefore, in the illustrated embodiment, the load system 300 includes a protection circuit 304 for protecting the base-emitter junctions of the transistors. The protection circuit operates to protect the base-emitter junctions of the transistors during both off-state and on-state.

FIG. 3B illustrates a schematic diagram of an active load system 300 according to an embodiment of the present invention. In the illustrated embodiment, the load system 300 includes bipolar transistors Q₁ through Q₄ in a bridge configuration. Thus, the transistor bridge is configured such that base terminals of transistors Q₁ and Q₃ are tied together to form an input to the bridge. The voltage at this input connection node is designated as V₀. The collector terminal of transistor Q₁ is coupled to a low voltage supply, V_{EE}. Emitter terminals of transistors Q₁ and Q₂ are tied together at node A. This node is coupled to a first current source such as current sink I_{SINK}, through switch S₃. Moreover, base and collector terminals of transistor Q₂ are tied together, and to base and collector terminals of transistor Q₄, at an output node. The voltage at this output node is designated as V_{DUT} because this node is coupled to a DUT pin. Furthermore, emitter terminals of transistors Q₃ and Q₄ are tied together at node B. This node is coupled to a second current source such as current source I_{SOURCE}, through switch S₄. The collector terminal of transistor Q₃ is coupled to a high voltage supply, V_{CC}.

As can be seen in FIG. 3B, transistors Q₁ and Q₂ are implemented with PNP transistors while transistors Q₃ and Q₄ are implemented with NPN transistors. However, these transistors may be implemented with different combinations of NPN and PNP transistors. Further, alternative connections of the transistor terminals may be made without significantly affecting the performance of the transistor bridge. For example, instead of coupling the collector terminal of transistor Q₁ to a low voltage supply (V_{EE}) and the collector terminal of transistor Q₃ to a high voltage supply (V_{CC}) both collector terminals may be tied together to the input connection node.

The protection circuit includes a plurality of buffers, which may be configured into a high impedance state. In the illustrated embodiment, buffers B₃ and B₄ are disposed between base and emitter terminals of transistors Q₂ and Q₄, respectively. The input terminals of the buffers B₃ and B₄ are connected to the base terminals of the transistors Q₂ and Q₄ while the output terminals of the buffers B₃ and B₄ are connected to the emitter terminals of the transistors Q₂ and Q₄. In one state, the emitter terminals of the transistors may be configured to hold the same voltage as that of the base terminals. In another state, the emitter terminals of the transistors may be configured to be isolated from the base terminals (i.e. in a tri-state) in response to a control signal. The circuit also includes a diode bridge having Schottky diodes, D₁ and D₄, to provide reverse bias protection for the base-emitter junctions of the bipolar transistors. Output of the diode bridge is coupled to node C. Furthermore, buffer B₁ is disposed between the output node and node C through a resistor, R. Buffer B₂ is disposed between node C and the input connection node, whose voltage is designated as V₀. Buffer B₂ drives the input connection node and isolates resistor R from the capacitance of transistors Q₁ and Q₃. However, if transistors Q₁ and Q₃ can be made small in size to provide lower driving current, buffer B₂ may be eliminated from the configuration.

The diode bridge having Schottky diodes, D₁ through D₄, is coupled to a commutation voltage, V_{COM}, and node C. Moreover, current nodes X and Y are coupled to current sources I_{B1} and I_{B2}, respectively. These current sources I_{B1} and I_{B2} are coupled to the current nodes through switches S₁ and S₂, respectively.

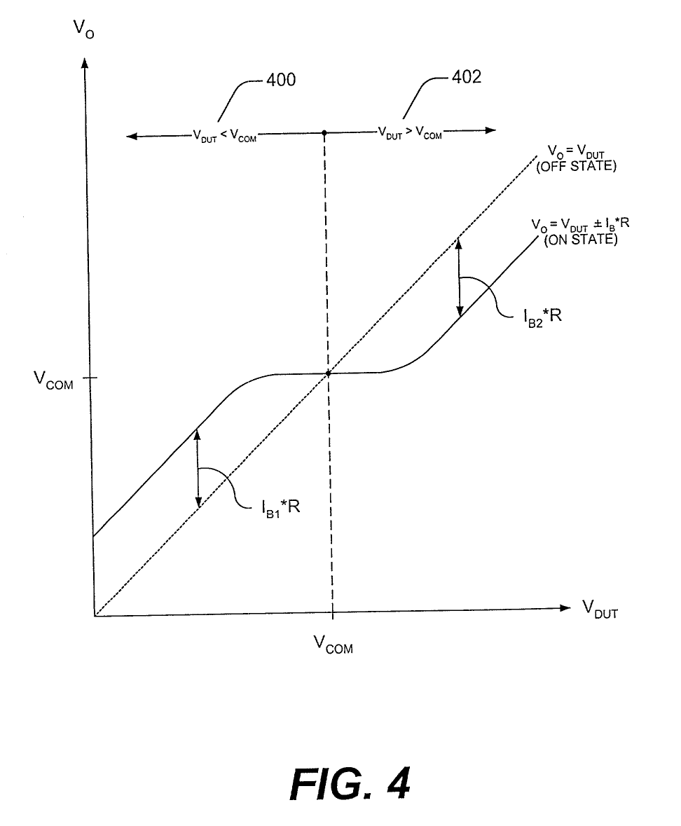

The operational state of the load system 300 is described below in relation to the plot of FIG. 4, which illustrates V₀ versus V_{DUT} plots. In the description, the operational state includes both an off-state and an on-state of the transistor bridge. Thus, the description of the operational state of the load system 300 also describes the method for providing a load to a DUT pin.

In the off-state, current switches S₁ through S₄, of FIG. 3B, are turned off. This enables buffers B₁ and B₂ to feed the output voltage (V_{DUT}) back to the input node, to make V₀=V_{DUT}. This is represented by a dotted line shown in the plot of FIG. 4. Furthermore, buffers B₃ and B₄ are configured into a non-tri-state. By de-asserting the tri-state input (HiZ) to the buffers, nodes A and B are driven to V_{DUT} by buffers B₃ and B₄, respectively. Thus, emitter terminals of transistors Q₁ and Q₄ are driven to V_{DUT}. The base terminals of transistors Q₁ and Q₃ are tied to voltage V₀ (which is equal to V_{DUT}), while the base terminals of transistors Q₂ and Q₄ are tied to voltage V_{DUT}. Hence, base-to-emitter voltages (V_{BE}) of transistors Q₁ through Q₄ are adjusted to substantially equal to zero. This provides low leakage current (i.e. less than 10 nA) in the transistors of the transistor bridge.

In some embodiments, buffers B₁ through B₄ may be implemented as any type of high-speed buffers such as emitter-followers or diamond-followers. In the diamond-follower, small amounts of offset are acceptable because moderate forward or reverse bias (i.e. less than 50 mV) causes relatively small leakage current (i.e. less than 10 nA). However, these buffers may be implemented as any type of buffers.

In the on-state (i.e. commutation state), a feedback network is connected by turning on current switches S₁ through S₄. In the illustrated embodiment of FIG. 3B, the diode bridge (including Schottky diodes D₁ through D₄), resistor R, and buffers B₁ and B₂ operate to compare the input commutation voltage, V_{COM}, with the output voltage at the DUT pin, V_{DUT}. Furthermore, buffers B₃ and B₄ are configured into tri-state to isolate the output (V_{DUT}) from nodes A and B. This enables base-to-emitter voltages of the transistors to be appropriately adjusted.

In operation, when V_{DUT} is less than V_{COM}, diodes D₂ and D₃ are forward biased while diodes D₁ and D₄ are reverse biased. Thus, this mode injects current I_{B1} into node C. Moreover, the diode bridge, resistor R, and buffer B₂ operate to add voltage I_{B1}*R to V_{DUT} to provide V₀=V_{DUT}+I_{B1}*R. Hence, in this mode, the transistor bridge operates in region 400 shown in FIG. 4.

Further, when V_{DUT} is greater than V_{COM}, diodes D₁ and D₄ are forward biased while diodes D₂ and D₃ are reverse biased. Thus, this mode sinks current I_{B2} away from node C. Moreover, the diode bridge, resistor R, and buffer B₂ operate to subtract voltage I_{B2}*R from V_{DUT} to provide V₀=V_{DUT}−I_{B2}*R. Hence, in this mode, the transistor bridge operates in region 402 of FIG. 4. V₀ versus V_{DUT} plot for the on-state or commutation-state operation is shown as a solid line in FIG. 4. Therefore, this curve shows that the protection circuit limits the reverse bias voltage on the base-emitter junctions of the transistors. Accordingly, the value of the current sources I_{B1} and I_{B2}, as well as the value of the resistor R, should be appropriately selected to limit the reverse bias voltage on the base-emitter junctions of the transistors to a tolerable level.

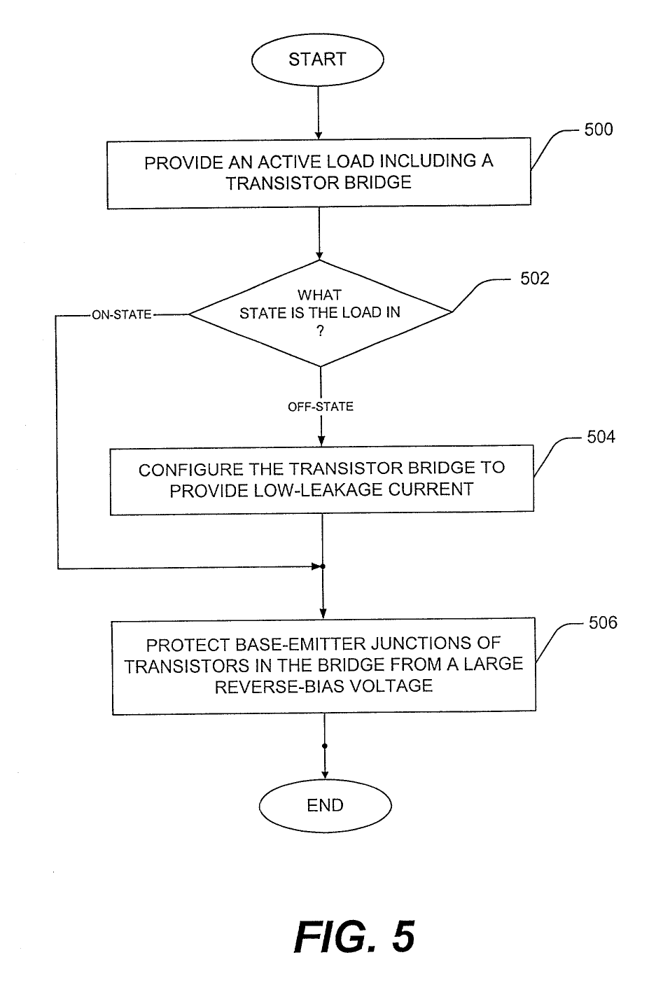

FIG. 5 is a flowchart illustrating a method for providing a load to a DUT pin during automatic testing of a device in accordance with an embodiment of the present invention. The method includes providing a load including a transistor bridge at 500. Determination of the load state is then made, at 502. The transistor bridge is configured to provide low-leakage current (at 504) when the load is in an off-state. The base-emitter junctions of the transistors in the bridge are protected (at 506) from a large reverse-bias voltage.

There has been disclosed herein embodiments for providing a load for a DUT during an automatic testing of a device. In particular, the load may include bipolar transistors. Thus, in one embodiment, the load is configured to replace the Schottky diodes in the bridge with bipolar transistors, which exhibit low leakage current in the off-state. Moreover, the load also includes a protection circuit for protecting the base-emitter junctions of the transistors from a large reverse bias voltage.

While specific embodiments of the invention have been illustrated and described, such descriptions have been for purposes of illustration only and not by way of limitation. Accordingly, throughout this detailed description, for the purposes of explanation, numerous specific details were set forth in order to provide a thorough understanding of the present invention. It will be apparent, however, to one skilled in the art that the embodiments may be practiced without some of these specific details. For example, although the transistor bridge is illustrated in FIG. 3B as being configured with bipolar transistors, other transistors, such as field-effect transistors, may be used. In other instances, well-known structures and functions were not described in elaborate detail in order to avoid obscuring the subject matter of the present invention. Accordingly, the scope and spirit of the invention should be judged in terms of the claims which follow.

What is claimed is:

1. A load system for a device under test, comprising:
a transistor bridge having a plurality of transistors, said transistor bridge providing low leakage current during an off-state of the load system; and
a protection circuit to protect base-emitter junctions of said plurality of transistors from a large reverse bias voltage.

2. The system of claim 1, wherein said plurality of transistors in the transistor bridge includes at least first, second, third, and fourth transistors.

3. The system of claim 2, wherein each of said first, second, third, and fourth transistors have a base terminal, a collector terminal, and an emitter terminal, where the base terminals of said first and third transistors are coupled together, the base terminals and the collector terminals of said second and fourth transistors are coupled together, the emitter terminals of said first and second transistors are coupled together, the emitter terminals of said third and fourth transistors are coupled together, the collector terminal of said first transistor is tied to a low voltage supply, and the collector terminal of said third transistor is tied to a high voltage supply.

4. The system of claim 3, further comprising:
an output node coupled to the common base and collector terminals of said second and fourth transistors, where said output node also couples to a pin of the device under test.

5. The system of claim 4, further comprising:
a first buffer disposed between said output node and the emitter terminal of said second transistor; and
a second buffer disposed between said output node and the emitter terminal of said fourth transistor,
where said first and second buffers provide high-impedance output to the emitter terminals, and provide low leakage current for the transistor bridge during an off-state of the load system.

6. The system of claim 2, further comprising:
a first current source for providing current into the device under test; and
a second current source for sinking current out of the device under test.

7. The system of claim 6, wherein said first current source is coupled to the common emitter terminals of said first and second transistors.

8. The system of claim 6, wherein said second current source is coupled to the common emitter terminals of said third and fourth transistors.

9. The system of claim 1, wherein said plurality of transistors includes bipolar transistors.

10. The system of claim 1, further comprising:
an input node arranged to receive a commutation voltage; and
an output node coupled to a pin of the device under test.

11. The system of claim 10, wherein said protection circuit includes a diode bridge and a resistor, where said diode bridge is disposed between said input node and said transistor bridge.

12. The system of claim 11, wherein the diode bridge includes a plurality of diodes arranged to provide reverse bias protection for base-emitter junctions of said plurality of transistors, in conjunction with said resistor.

13. The system of claim 12, wherein said plurality of diodes includes Schottky diodes.

14. The system of claim 11, further comprising:
third and fourth current sources coupled to said diode bridge to source and sink current.

15. The system of claim 11, further comprising:
a third buffer disposed between said output node and said resistor.

16. The system of claim 15, further comprising:
a fourth buffer disposed between said diode bridge and said transistor bridge.

17. The system of claim 2, wherein each of said first, second, third, and fourth transistors have a base terminal, a collector terminal, and an emitter terminal, where the base terminals of said first and third transistors are coupled together, the base terminals and the collector terminals of said second and fourth transistors are coupled together, the emitter terminals of said first and second transistors are coupled together, the emitter terminals of said third and fourth transistors are coupled together, the collector terminals of said first and third transistors are coupled together.

18. The system of claim 17, further comprising:
an output node coupled to the common base and collector terminals of said second and fourth transistors, where said output node also couples to a pin of the device under test.

19. The system of claim 18, further comprising:
an input node coupled to the common collector terminals of said first and third transistors.

20. A method for providing a load to a DUT pin during automatic testing of a device, comprising:
providing a transistor bridge having a plurality of transistors;
determining whether a state of the load is an off-state or an on-state;
configuring the transistor bridge to provide low-leakage current when the load is in the off-state; and
protecting base-emitter junctions of said plurality of transistors from a large reverse-bias voltage.

21. The method of claim 20, wherein said configuring the transistor bridge to provide low-leakage current includes turning off said plurality of transistors, and holding base-to-emitter voltages of said transistors substantially close to zero.

22. The method of claim 20, wherein said protecting base-emitter junctions of said plurality of transistors includes comparing a commutation voltage at an input node with a DUT voltage at an output node coupled to the DUT pin.

23. The method of claim 22, wherein said protecting base-emitter junctions of said plurality of transistors further includes isolating the output node from emitter terminals of said plurality of transistors.

24. The method of claim 22, further comprising:
adding a voltage equivalent to a product of a sink current of a diode bridge and a resistor from the DUT voltage to produce an input voltage for the transistor bridge when the DUT voltage is less than the commutation voltage.

25. The method of claim 22, further comprising:
subtracting a voltage equivalent to a product of a sink current of a diode bridge and a resistor from the DUT voltage to produce an input voltage for the transistor bridge when the DUT voltage is greater than the commutation voltage.
